(19) United States
(12) Patent Application Publication
(10) Pub. No.: US 2009/0212216 A1
(43) Pub. Date: Aug. 27, 2009

(54) Mining methods and apparatus

(75) Inventors: Chad Owen Hargrave, Queensland (AU); David Charles Reid, Queensland (AU); David William Hainsworth, Queensland (AU); Jonathan Carey Ralston, Queensland (AU); Michael Shawn Kelly, Queensland (AU); Ronald John McPhee, Queensland (AU)

Correspondence Address: MERCHANT & GOULD PC, P.O. BOX 2903, MINNEAPOLIS, MN, 55402-0903, US

(73) Assignee: Commonwealth Scientific and Industrial Research Organisation, Campbell, ACT (AU)

(21) Appl. No.: 11/913,838

(22) PCT Filed: May 11, 2005
(86) PCT No.: PCT/AU05/00674

§ 371 Date: Nov. 12, 2008

(51) Int. Cl. H01L 25/00; E21C 35/08; E21C 35/24; E21C 41/00; E21C 27/00

(52) U.S. Cl. 250/332; 299/1.1

(57) ABSTRACT

A method and apparatus for horizon control in a mining operation is provided. Fresh product 3 is cut from a seam 1. The cutting exposes a fresh cut product face 25. The fresh cut product face 25 is observed at a position immediately adjacent a cutter 11. Any temperature contrast regions from an IR observation between an upper limit of observation and a lower limit of observation are noted. At least one height co-ordinate position of a temperature contrast region 33 is determined and an output signal provided of the determined height co-ordinate position so that the output signal can be used as a horizon datum for horizontal control.

### FIELD OF THE INVENTION

This invention relates to mining methods and apparatus and relates particularly but not exclusively to mining methods and apparatus suitable for longwall mining applications. The invention has application in other mining applications and is not to be limited to longwall mining exclusively.

### BACKGROUND ART

Hitherto, it has been known to provide mining methods and apparatus to control mining of product from a seam of product in the mine. One known longwall mining method involves observing infrared (IR) radiation from a fresh cut product face at a position immediately adjacent the cutter at the region where a vertical wall of cut intersects with either an upper or lower wall of cut. Such method determines either an upper or lower limit of the seam of the product in the mine by noting if there is an IR temperature increase at the intersection of the vertical cut wall and either the horizontal cut floor or horizontal cut roof. An IR temperature increase occurs when a cutter cuts into strata in the roof or floor immediately above or below the seam of the product. This is because the strata is usually harder than the production in the seam and therefore the strata heats more during the cutting process than the product. Thus, by noting an IR temperature increase at this region, one can determine the upper and/or lower limits of the seam of the product in the mine. Signals can be generated defining the upper limit or lower limit of the seam so that the mining machine can be controlled to cause the cutter to not cut into the overlying or underlying strata.

Such methods and apparatus are useful, however, such methods and apparatus do have their failings and it is possible for the overlying or underlying strata to be mined and cut with the product from time to time. This places undue loadings on the mining equipment, dilutes product content and gives rise to other production problems including an increase in dust within the mine which, in turn, affects personnel safety within the mine.

### OBJECT AND STATEMENT OF THE INVENTION

There is a need for an improved method and apparatus.

According to one aspect of the invention there is provided a method of horizon control in a mining operation where mined product is cut from a mining face of a seam of the product, said method comprising,

cutting product from the seam with a cutter that exposes a fresh cut product face

visually observing the IR radiation from the fresh cut product face at a position immediately adjacent the cutter,

Noting any temperature contrast regions from the IR observation between an upper limit of observation and a lower limit of observation,

Determining at least one height co-ordinate position of at least one temperature contrast region, and

generating an output signal of the determined height co-ordinate position so the generated output signal can be used as a horizon datum for horizon control.

According to another aspect of the invention there is provided a sensing apparatus for operating with mining machine horizon controlling apparatus,

said sensing apparatus having an image acquisition section for receiving IR image signals of an observed position of a fresh cut mined product face immediately adjacent a mining machine cutter

a signal processing component to process the acquired IR image signals to note for at least one temperature contrast region between an upper part of the image and a lower part of the image,

a height position component to receive any noted temperature contrast region processed by the signal processing component and to calculate a height position of the at lest one noted temperature contrast region, and

a signal output component to provide an output signal of the calculated height position for said mining machine horizon controlling apparatus.

According to another aspect of the invention there is provided a method of identifying thermally identifiable structure in a product mined from a mining face in a mine where a cutter cuts the product and exposes a fresh cut product face,

said method comprising visually observing the IR radiation from the fresh cut product face immediately adjacent the cutter,

noting at least one temperature contrast region from the IR observation and determining a thermally identifiable structure in the product mined by either;

1. the size magnitude of at least one temperature contrast region or,

2. contrast region above a temperature threshold.

According to another aspect of the invention there is provided an apparatus to identify thermally identifiable structure in a mined product when mining product from a mine,

said apparatus having an image acquisition section for receiving IR image signals of an observed position of a freshly exposed cut product face immediately adjacent a mining machine cutter that cuts product from the mine,

a signal processing component to process the acquired IR image signals to note at least one temperature contrast region,

an image processing component to identify thermally identifiable structure of the mined product by either

1. noting the size magnitude of the at least one temperature contrast region, or

2. noting the magnitude of the at least one temperature contrast region above a temperature threshold, and

an output component to provide an output indicating thermally identifiable structure in the mine product.

### BRIEF DESCRIPTION OF THE DRAWINGS

In order that the invention can be more clearly ascertained examples of embodiments of the invention will now be described with reference to the accompanying drawings based on a longwall mining application. As stated previously, the invention is not to be limited to longwall mining applications and the description hereinafter is to be taken as an example. For other mining applications, the principles outlined herein can be utilised in a similar way.

In the drawings:

FIG. 1 is a diagrammatic perspective view of a longwall mining process deep within the earth,

FIG. 2 is a schematic diagram similar to FIG. 1 showing a mined product seam exhibiting an IR contrast region, in the form of a band, at a fresh cut product face,

FIG. 3 is a diagrammatic view showing a field of view of an IR camera that observes a fresh cut product face at a position in the region of a cutter and between a lower limit of the seam and an upper limit of the seam,

FIG. 4 is a diagram showing the field of view of the IR camera as shown in FIG. 3 but showing a datum position for noting temperature contrast regions,

FIG. 5 is a graph showing image pixel grey scale intensity levels of pixels measured along the datum shown in FIG. 4,

FIG. 6 is a graph showing the height of a thermal contrast region-V-mining machine position,

FIG. 7 is a functional block circuit schematic diagram showing apparatus for processing the IR contrast region picture image signals obtained from an IR camera visually observing the IR radiation from the fresh cut product face,

FIG. 8 is a processing algorithm utilised with the apparatus schematically shown in FIG. 7,

FIG. 9 is a view similar to that in FIG. 3 but showing a second IR observation of the freshly cut product face to determine an upper or lower limit of the seam,

FIG. 10 is a block schematic diagram similar to that shown in FIG. 7 but showing the addition of components for processing upper and/or lower limits of the seam of the product,

FIG. 11 is an algorithm for use with the apparatus shown in FIG. 10 in so far as determining the upper and or lower limits of the seam,

FIG. 12 is an algorithm showing outputs for use in horizon control of a mining machine, and

FIG. 13 is a functional diagram showing automated horizon control in a mining machine.

### DETAILED DESCRIPTION OF EXAMPLE OF PREFERRED EMBODIMENT

In the description that follows, a longwall mining application is discussed. As stated previously, the inventive concepts are not to be limited to longwall mining. The inventive concepts can be practised in other mining applications/techniques and the invention is to be considered to extend to those other mining applications/techniques as well.

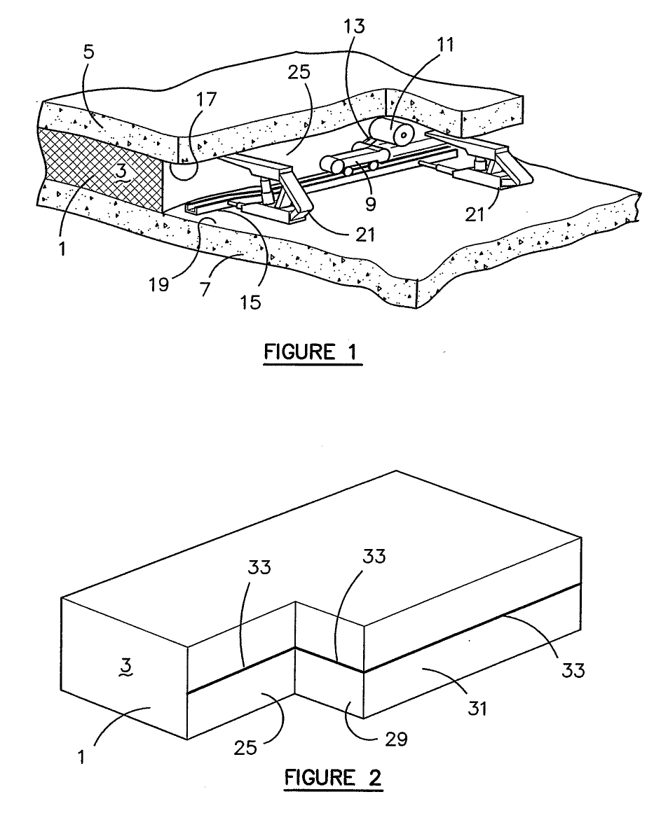

FIG. 1 is a diagrammatic perspective view showing a seam 1 of product 3 in a mine. Typically, the product 3 is coal but it may be other material. Coal is usually deposited in the seam 1 in layers. The seam 1 is bounded by upper strata 5 and lower strata 7. The coal may be deposited in layers of different geological materials such as the coal itself, clay or ash or other material of varying thickness and hardness. This layering may appear as thin horizontal line-like bands in the seam 1 of the coal. These line-like bands are strongly linked to the profile of the seam 1. Because these line-like bands are strongly linked to the profile of the seam 3, we have realised that by noting one or more of these line-like bands we can provide a means for setting a datum for mining machine horizon control. Typically, the bands are not always clearly visible with the naked eye and some automated process is required to detect the one or more bands and to provide output signals that can be used by a mining machine conventional horizon control circuit for controlling the horizon position of the mining machine and the cutter carried thereby.

FIG. 1 shows a partly mined mine where a mining machine 9 carries a rotating cutter drum 11. The cutter drum 11 is carried on an arm 13 that can swing up and down relative to the mining machine 9. The mining machine 9 is carried on a rail means 15 that extends across the width of the seam 1 (or at least across width of the intended mining area of the seam 1). The mining machine 9 moves along the rail means 15 and the arm 13 is raised or lowered so the rotating cutter drum 11 cuts product 3 from the seam 1. In some instances, the mining machine 9 may have a second arm 13 and cutter drum 11 located at the other end of the mining machine 9. In this case one of the cutter drums 11 cuts product 3 from seam 1 up towards a roof 17 of the mine and the other cutter drum 11 cuts downwardly towards a floor 19 of the mine. Typically, the roof 17 is determined at the interface between the seam 1 and the upper strata 5. Similarly, the floor 19 is determined at the interface between the seam 1 and the lower strata 7. The overhanging roof 17 is supported by a plurality of chocks 21. Only two chocks 21 have been shown, but in practice, there are many chocks 21 spaced adjacent one another along the length of the rail means 15. The chocks 21 connect at their lower foot region with the rail means 15 and can be manipulated to push the rail means 15 forwardly towards the seam following passing of the mining machine 9. The chocks 21 can be further manipulated to then draw themselves as a whole towards the rail means 15 moving the upper supporting arms 23 close to the fresh cut product face 25 of the seam 1. The technique for moving the mining machine 9 and swinging the cutter drums 11 and the movement of the chocks 21 is considered known in the longwall mining arts per se and will not be detailed further herein.

FIG. 2 is an exploded perspective view showing the seam 1 of the product 3 as shown in FIG. 1 without the upper strata 5, lower strata 7, mining machine 9 and chocks 21. Here, it is clearly shown that the mining machine cutter drum 11 has cut a fresh cut product face 25 which comprises an upright wall 27 that extends from side to side across the seam 1. It also comprises an upright end wall 29 that has a depth into the seam equal to the depth of the cutter drum 11. FIG. 2 also shows a previously cut product face 31 that extends parallel to the fresh cut product face 25. FIG. 2 also shows a single band or feature 33 that extends throughout the seam 1. In practice, there may be one or more bands or features 3, all approximately extending in planes parallel to one another. The bands or features 33 are generally planar but there are some falls and other contours present due to the nature of layering of the seam 1. Typically, the band or feature 33 is formed from a material deposit that is of greater hardness than that of the product 3 itself. In some cases, the band or feature 33 may be visibly discernible with the naked eye but it may also be non visible to the naked eye.

We have found that if the IR radiation emitted from the fresh cut product face 25 adjacent the cutter 11 is observed, then the band or feature 33 shows a higher IR radiation level than the level of the surrounding product 3. This is presumably because the cutter 3 heats the material of the band or feature 33 greater than that of the product 3 during the cutting/mining process. Accordingly, by observing the IR radiation from the fresh cut product face 25 at a position immediately adjacent the cutter 11, it is possible to note for any temperature contrast regions from the IR observation between an upper limit of observation and a lower limit of observation. In this way, if the upper limit is ideally just below the interface between the seam 1 and the upper strata 5 and/or the lower strata 7, then any noted contrast regions will be indicative of the presence of a band or feature 33. The band or feature 33 position can then be used for horizon controlling the mining machine 9. As the band or feature 33 is generally parallel to the upper or lower limit of the seam 1 with regard to the roof 17 or the floor 19, providing a datum based on at least one contrast region permits an ideal mechanism for horizon datum setting for mining machine 9 control.

In the example of the preferred embodiment a PAL long wavelength (8-14 micron) thermal IR video camera at 25 fps is used to provide a digital picture image of the fresh cut product face 25. It may also be possible to use a CCD video camera which is sensitive to short wavelength (1-3 micron) thermal IR radiation for visually observing the fresh cut product face 25. The image capture device may be appropriately chosen to suit the particular product being mined and the mining environment. When a video camera is used, analysis of the resulting digital picture image may be made at each frame or at selected frames say every 25^{th} frame. Alternatively, a thermal IR still camera may be utilised and images generated at predetermined time intervals consequent on the speed of movement of the mining machine 9 across the face of the seam 1 during the mining operation. In the present example, the imaging device is a digital thermal IR video camera that observes the fresh cut product face 25 that extends in a direction across the width of the mining of the seam 1 and every frame is analysed, as this increases sensitivity of the system to low thermal IR values compared to analysing at say every 25^{th} frame. In an alternative arrangement the fresh cut product face may be the upright end wall 29 representing the depth of cut of the cutter drum 11. This alternative is to be considered within the scope of the invention. Desirably, the camera views a region of interest in the fresh cut product face 25 in the immediate vicinity of the cutter drum 11. In this way, the residual IR radiation will be expected to be near a peak level and where the temperature will not have dissipated due to passage of time following the passing of the cutter drum 11.

The infrared sensitivity of a thermal infrared camera has particular advantage over standard visible-wavelength cameras in mining operations. In particular, long wavelength thermal infrared cameras are highly insensitive to occlusions caused by dust. Thermal IR cameras can also function in total darkness which further makes IR cameras of this type suitable for practical implementation. The field of view 34 encompassing the region of interest 35 of the camera is likely to show important features of interest that appear in the thermal domain that may not otherwise appear in the visible domain. A typical position for mounting of the camera is on the body of the mining machine 9 and oriented such that the camera has a viewable aspect at the region of interest of the cutter drum 11 and any surrounding seam 1 or strata 5,7 and so that it is protected from rough operational conditions of mining.

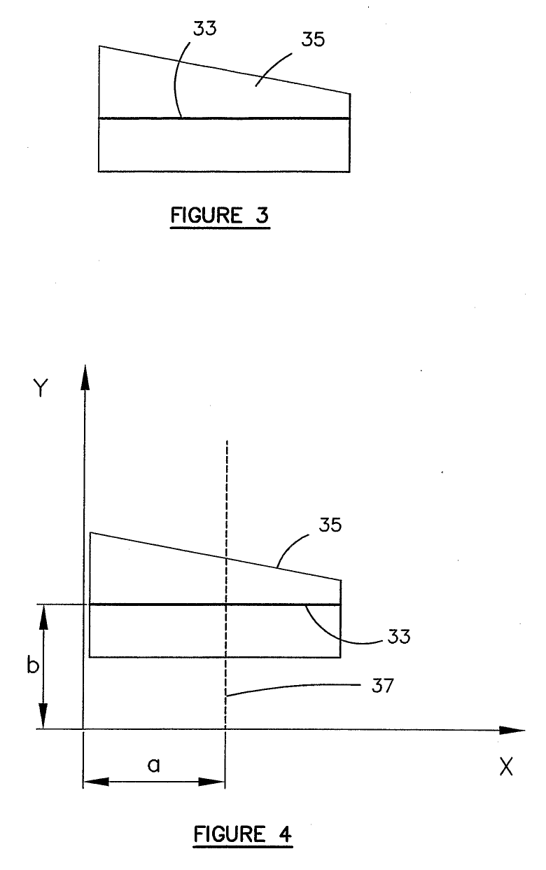

FIG. 3 shows a field of view 34 encompassing the region of interest 35 of the digital video camera. In this case, the region of interest 35 is somewhat trapezoidal in shape. This is consequent on the angle of inclination of the camera relative to the fresh cut product face 25. The region of interest 35 is selected within the picture image 34 by selecting particular pixels to define the area of the region of interest. FIG. 3 shows a single band or feature 33 but other bands or features 33 may be present.

FIG. 4 shows the setting of a viewing datum 37 at a distance “a” from a zero position on a horizontal axis “X”. The datum position 37 extends in a vertical axis direction “Y” up and down the height of the field of view 35 of the IR radiation. FIG. 4 shows that the datum position 37 has a point of intersection with the band or feature 33 at a height “b” in the “Y” (vertical) direction. Thus, by determining a co-ordinate relating to the intersection of the datum position 37 with the band or feature 33, one can note the position of the band or feature 33 and use the co-ordinate position to horizon control the mining machine 9.

It should be appreciated that as the mining machine 9 moves across the seam 1 the field of view 34 will also move and the position of the one or more bands or features 33 will be tracked. Thus, as the seam 1 moves up or down, the band or feature 33 would be expected to move in unison, and continual control of the mining machine 9 can be achieved by noting the height of the intersection position of the datum position 37 with the band or feature 33. Thus, should the height position of the band or feature 33 change then there will be a corresponding change in the co-ordinate position of the intersection which can be used to provide a signal for controlling the mining machine 9.

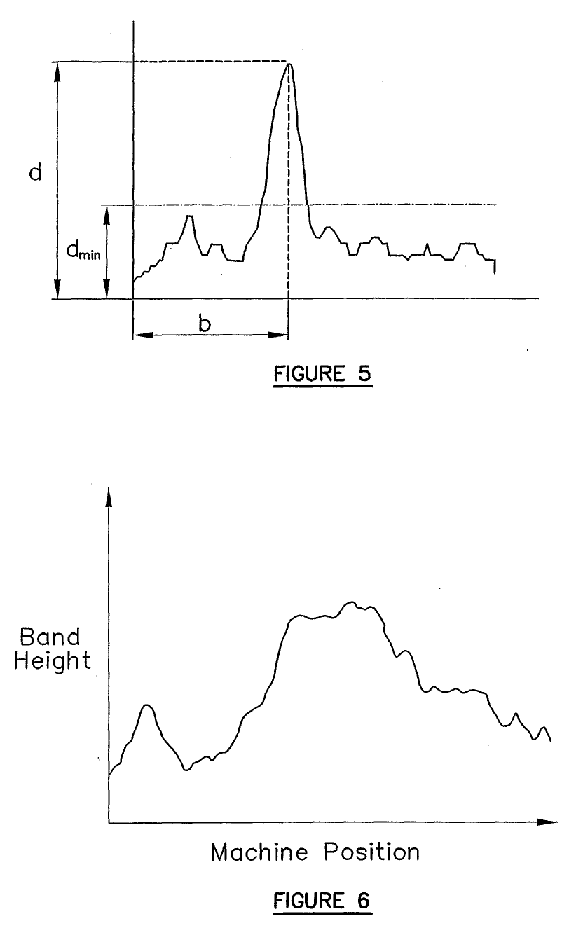

Referring now to FIG. 5 there is shown a plot of IR pixel intensity value levels determined from the camera with respect to the background in the region of interest 35 in the field of view 34. In the example herein, the datum position 37 is defined by specific pixel locations in the digital picture image obtained from the digital video camera. FIG. 5 shows the grey scale pixel intensity value levels of the pixels along the datum position 9 extending in a direction up and down the height of viewing. The graph shows a peak in the pixel grey scale intensity values at a height distance “b” in FIG. 4. In FIG. 5, the height distance “b” is shown along the horizontal axis. Here, a localised peak 39 appears in the pixel grey scale intensity values at height “b”. The magnitude of the localised peak 39 is shown by ordinate “d”. FIG. 5 also shows that a threshold value having an ordinate “dₘᵢₙ” can be set. Thus, if the localised peak 39 exceeds the threshold value of dₘᵢₙ, this then represents a temperature contrast region relative to the surrounding background. This, in turn, represents the height positioning of a band or feature 33. Typically, dₘᵢₙ is set to be just above the background threshold level of IR radiation emitted from the fresh cut product face 25 for the known composition of the product 3 such as coal. The threshold value represented by dₘᵢₙ is necessary to cater for instances where the band or feature 33 is either not present or poorly discriminated from the background. If the largest value of “d” of the vertical line grey scale pixel intensity data is equal to or greater than a given minimum band detection threshold dₘᵢₙ, then the index “b” (along the horizontal axis) associated with the maximum value “d” is taken to be a valid location of the temperature contrast region (and the band or feature) in the image. If the value “d” is less than the threshold value dₘᵢₙ then no height determination is calculated.

Any tracking of the band or feature 33 needs to take into account errors and observation noise associated with the detection and/or localisation processes. This is particularly important in cases where the band or feature 33 appears relatively faint in the IR image. In some cases, the intensity values may be so high with respect to the background that no special processing may be required. In the case where there may be a relatively faint IR localised peak 39, then a robust filter tracking feature may be implemented. A “Kalman” filter represents a particularly useful robust filter and is well known filter for signal processing.

A Kalman filter recursively generates parameter estimates using a state vector, system model, and observation model. For this 1D position-velocity tracking scenario, the state vector is given by a (2×1) vector

$$x ( t ) = \begin{matrix}[ h ( t ) ] \\ [ v ( t ) ]\end{matrix}$$

which contains the true height h(t) and velocity v(t) of the band or feature 33 at time instant t. The system model is given by x(t+1)=F x(t)+w(t), where

$$F = \begin{matrix}[ 1 Δ T ] \\ [ 0 T ]\end{matrix}$$

is the (2×2) model matrix describing system evolution, ΔT represents the time between adjacent image frames, and where w(t) is a (2×1) matrix representing system perturbation to allow tracking of the marker band features. The matrix w(t) is assumed to be distributed as a zero-mean Gaussian noise process with (2×2) covariance matrix Q. The observation equation is given by b(t)=H x(t)+u(t), where b(t) is the height estimate generated by the band or feature 33 detector and location process at time instant t, H=[1 0] is the (1×2) vector, x(t) is the state vector as above, and u(t) represents the uncertainty associated with the marker band location algorithm. The value u(t) is assumed to be distributed as a zero-mean Gaussian process with variance R.

During initiation of a tracking process, the respective elements of the state vector are assigned the current band or feature 33 height and zero velocity, the diagonal elements of the system model covariance matrix Q are assigned to 0.01 representing a good model for the typically slowly evolving dynamics of band or feature 33, and the variance associated with observation equation R is set to a relatively large value of 10.0 following current practice to ensure convergence. The Kalman filter is implemented using standard prediction and update steps, the details of which are widely available in open literature.

The Kalman filter-derived estimates provide a superior representation to the observed band or feature 33 dynamics and show high noise immunity to unfiltered estimates. The Kalman filtering step, though not essential, proves particularly useful in cases where the intensity of the band or feature 33 is relatively faint (i.e., low SNR) as it represents a robust and deterministic method for dealing with noise and measurement uncertainty.

It should be appreciated that there may be many grey scale pixel intensity level peaks along the datum, each peak representing a different band or feature 33. Further, these peaks may have different peak pixel intensity values. These may all be processed to determine if they exceed the threshold, and all of these, or selected ones of these used for horizon control.

FIG. 6 shows a plot of the band or feature 33-V-mining machine 9 position. The actual noting of the height co-ordinate of the band or feature 33 is inherently a spatial quantity. It is convenient in a mining machine operation to refer the band or feature 33 height co-ordinate in terms of position instead of time. This is easily done by noting the values of the height of the band or feature 33 against the mining machine 9 position. FIG. 6 illustrates a typical output from a tracking algorithm (to be referred to later) showing the band or feature 33 height as a function of horizontal face position of the mining machine 9 across the width of seam 1.

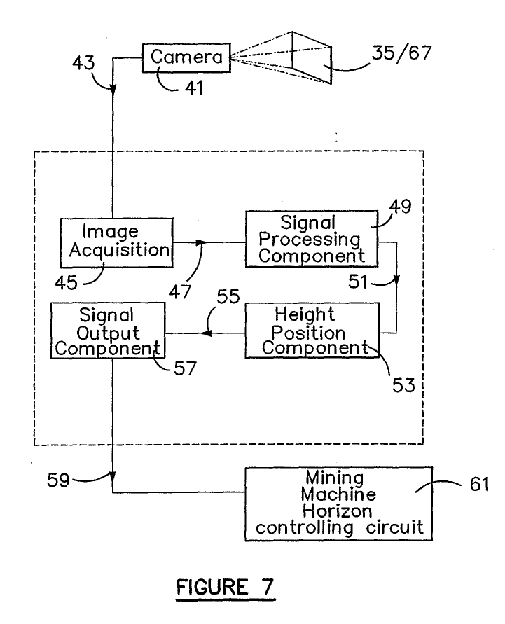

FIG. 7 is a block schematic diagram showing components of apparatus used for providing a signal output for mining machine horizon control. Here, the apparatus utilises the concepts hereinbefore described. A thermal IR digital video camera 41 observes the fresh cut product face 25 and has a field of view 34 encompassing a region of interest 35. Digital output signals 43 are supplied to an image acquisition component 45 for receiving the IR image signals of the fresh cut mined product face 25 immediately adjacent a mining machine cutter drum 11. Signals 47 are output from the image acquisition component 45 and supplied to a signal processing component 49 where the IR image signals in the region of interest 35 are noted for at least one temperature contrast region between an upper part of the image and a lower part of the image and between an upper limit of the seam and a lower limit of the seam. If at least one temperature contrast region is determined, then signals 51 are provided to a height position component 53 where a co-ordinate of the height position is calculated of the at least one noted temperature contrast region. Height position co-ordinate signals 55 are then provided to a signal output component 57 to provide an output signal 59 of the calculated height position of the at least one temperature contrast region so that that output signal 59 can be used in a mining machine horizon controlling circuit 61. The various components referred to in FIG. 7 can be discreet components or can be components within a computer device. Typically, the components are configured within a computer device using software dedicated for the purpose of configuring the computer to perform the functions required. Whilst the height position co-ordinate has been described as 1D, the co-ordinate may be 2D or 3D by appropriately inputting data signals of the absolute position of the mining machine 9 within the mine. Such signals can be obtained from inertial navigation components associated with the mining machine 9.

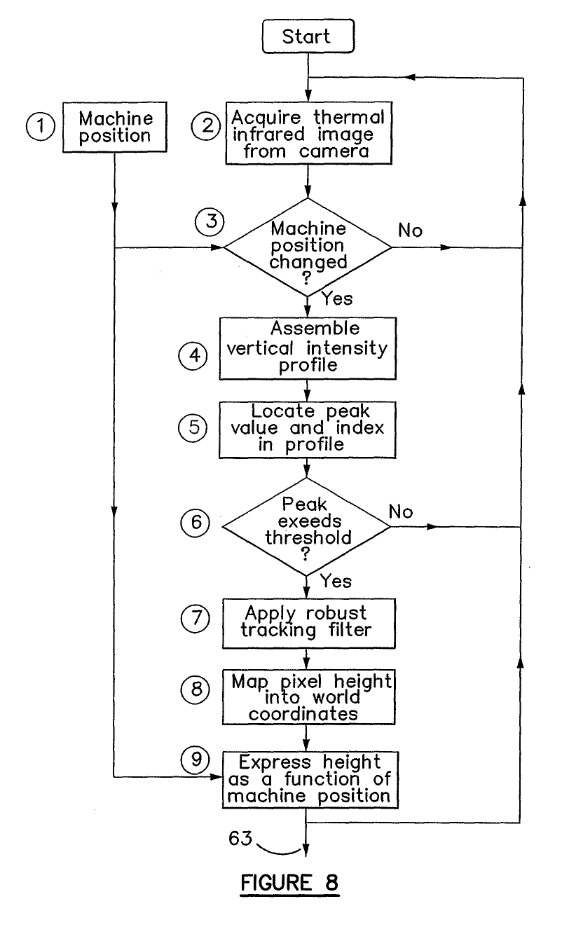

FIG. 8 shows an algorithm of the processes involved. Here, step 1 determines a mining machine position. A suitable position measurement apparatus is commonly provided on most large coal mining equipment such as longwall shearers or continuous miners. Thus, signals can be derived at step 1 representing the position of the mining machine 9. Independent known mining machine positioning means may be utilised to provide mining machine position signals if required. At step 2, the thermal infrared images are received using a direct-digital interface or by applying standard analogue to digital conversion techniques in the event the image is an analogue image. A typical thermal image is one shown by FIG. 4 herein. It should be noted that from the point of data acquisition, the output from a thermal IR video camera is analogous to a standard still image camera, that is, a sequence of still images in digital or analogue form. The algorithm shown in FIG. 8 processes each image frame sequentially, nominally regardless of acquisition rate. This frame selection is an arbitrary choice and is not meant to be limiting.

At step 3 machine position change sensing is determined. This is because unless the mining machine 9 has advanced across the face of the seam 3, there would be no need to reprocess an existing image acquired by the camera 41. Thus, signals from the machine positioning are compared to note if the machine 9 has moved and so that the image signals can be processed at step 4. In step 4, if a band or feature 33 is present, then it indicates a regional feature relative to the local background. Thus, a data set is formed by tracking the image pixel value at the datum position 37. This results in the generation of a data set similar to that shown in FIG. 5. At step 5, the localised peak 39 is determined by the intensity levels of the grey scale pixel values along the vertical datum line—up and down the height of viewing of the field of view 34 at the datum position 37. The brightest point in the pixel intensity values represents a localised peak 39. Step 6 determines if the peak 39 exceeds the set threshold represented by dₘᵢₙ (FIG. 5). At step 7 a robust tracking filter such as the Kalman filter described previously is applied. At step 8, the height of the localised peak 39 (height “b” in FIG. 4) is determined. It may be desirable to express this height value in other co-ordinate systems such as mining machine co-ordinate positions. This can be achieved by direct application of camera calibration techniques knowing the position of the camera on the mining machine 9.

It should be noted herein that the description so far relates to detecting a single band or feature 33 in the field of view 34 region of interest 35. Multiple bands or features 33 may be detected and the algorithm suitably processed to enable relative tracking of two or more of the noted bands or features 33. Thus, one or more of the noted bands or features 33 may be used to control for mining machine horizon control. This is particularly useful where one or more bands or features 33 may disappear in the region of interest 35 whilst other bands or features may remain.

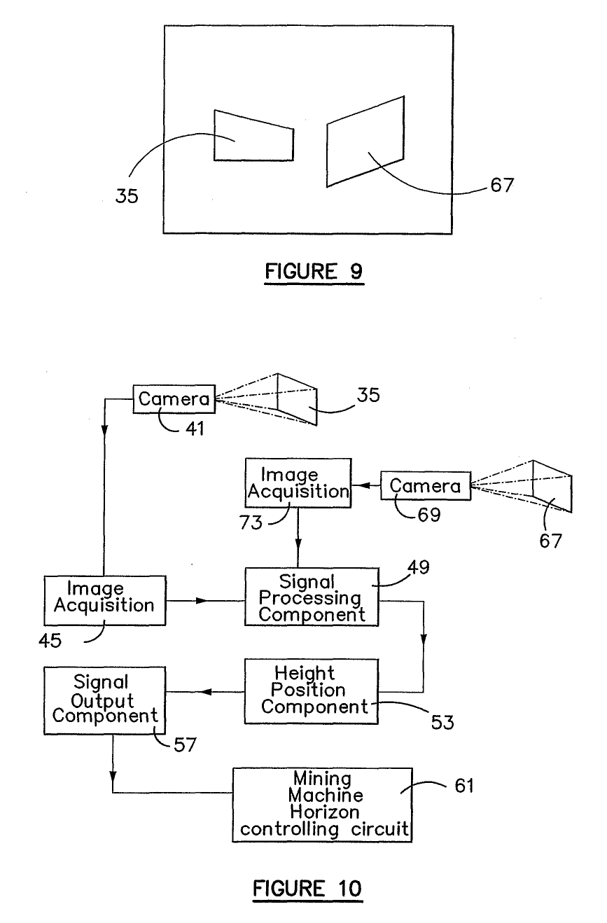

At step 9 the height co-ordinates determined at step 8 are transformed as a function of machine position as represented by FIG. 6 herein. Thus, an output signal 63 can be provided to a mining machine 9 for horizon control. Referring now to FIG. 9 there is shown a view similar to that of FIG. 3 but also showing a IR image second region of interest 67. Here, the second region of interest 67 is arranged to encompass an intersection of the vertical fresh cut face 25 with the roof 17 or floor 19. The area and position of the second region of interest is defined by pixel locations in the image of the field of view 34. Thus, a second region of interest 67 supplies further IR image signals to note for any temperature contrast region at the intersection of the vertical cut face 25 (see FIG. 2) and either or both the horizontal cut face of the roof 17 or floor 19. Here, any noted IR temperature contrast region defines the intersection of the seam 1 with the upper strata 5 and/or the lower strata 7. Thus, height position signals can be generated of those further IR image signals from the fresh cut product face to be used with the signals of the band or features 33 previously described for horizon control. Thus, in this case, the further IR image signals can be processed to provide height positions of the intersection of the vertical cut face 25 with the roof 17 or floor 19 to limit the extent of upward and/or downward movement of the arm 13 to, in turn, control the upper limit of seam mining and lower limit of seam mining. In this case, a second output signal is provided indicating the determined height co-ordinate position of the temperature contrast region at the intersection.

FIG. 10 shows a block schematic diagram of an arrangement having the band or feature 33 sensing apparatus described previously, and apparatus for noting the intersection of the vertical cut face with the roof 17 or the floor 19. In this example one IR video camera 41 is used for region of interest 35 and a further IR video camera 69 is used for the second region of interest 67. In the preceding discussion a single IR camera 41 was utilised to encompass both regions of interest 35, 67. In this example the second IR video camera 69 has been utilised to show that the concepts need not be limited to a single IR camera implementation. The left hand side components of FIG. 10 repeat the components shown in FIG. 7 herein and will not be described further. On the right hand side of FIG. 10 there is shown a second thermal IR video camera 69 having a field of view 67. Digital output signals 71 are fed to an image acquisition component 73. Signals 75 are output from an image acquisition component 73 and provided to the signal processing component 49. Here the signals are fed to a height position component 53 where the height co-ordinate positions of the temperature contrast regions that define the intersection of the vertical cut face 25 of the seam with the roof 17 and/or floor 19 are calculated. Here, the signals are output to the signal output component to define co-ordinate position signals which are supplied to the mining machine control circuit 61 for controlling the mining machine.

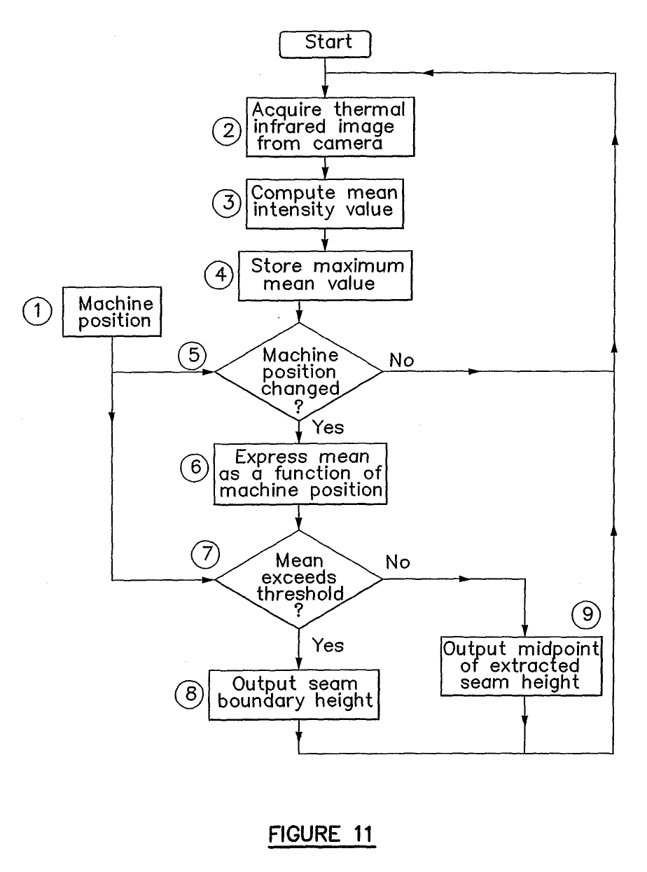

FIG. 11 shows a processing algorithm for detecting the fresh cut product face 25 intersection with the roof 17 or floor 19. This algorithm requires two parameters to be established during initial calibration. The first parameter corresponds to a threshold above which the coal seam interface with the roof 17 or floor 19 is assumed to have been reached. A detection threshold is set at 70% of the maximum intensity value and represents an appropriate initial choice. The second parameter is the seam extraction height which can be readily determined from the mining machine 9 itself using known processes.

At step 1 the machine position is ascertained according to the same processes described in relation to step 1 in FIG. 8. At step 2 image acquisition is performed and this again is identical to step 2 shown in FIG. 8 but from a different camera or region of interest within the image from a single camera. At step 3 a mean intensity value of all pixels in the image of the field of view is determined. If the mean intensity value changes, as noted by an averaging process of all the intensity value levels of the pixels in the image from the second camera 69, then it can be determined that there has been an intersection of the cutter drum 11 with the roof 17 or the floor 19. At step 4, a maximum mean pixel intensity value is stored. Such value may change significantly as the cutting drum 11 moves through segments of harder material (eg. rock) and provides a robust measure of any thermal intensity values. The maximum mean value is stored for the current machine 9 position.

At step 5 a process is invoked to determine if the machine horizontal position has changed. This is identical to step 4 in FIG. 8. At step 6, the magnitude of the mean intensity value computed at step 6 is compared to a pre-determined interface detection threshold. If the mean value is above the coal interface detecting threshold, then the coal seam interface is considered to be breached. Conversely if the mean value is below the coal interface then the mining machine is assumed to be cutting within the seam 1. At step 8 an output is provided of the seam interface positions of the interface with the roof 17 or the floor 19. This provides a maximum height for mining of the machine or a lower height for mining of the seam. In step 9, a mid point output signal is provided if no coal interface intersection is determined. This provides a suitable sentinel signal (eg. half the extracted seam height) to provide an output suitable for use in a horizon control system. Alternatively, a suitable sentinel signal can be established to run the mining machine control system in an open-loop mode.

The band or feature 33 tracking system described herein, and the coal interface detector for detecting the interface of the vertical fresh cut product face 25 with the roof 17 or the floor 19 provides two complimentary in-situ measures of the seam 1 behaviour. Whilst the outputs of the systems can be applied independently, they can also be usefully combined to provide a robust predictive-reactive sensing capability for use in real time horizon control of a mining machine 9.

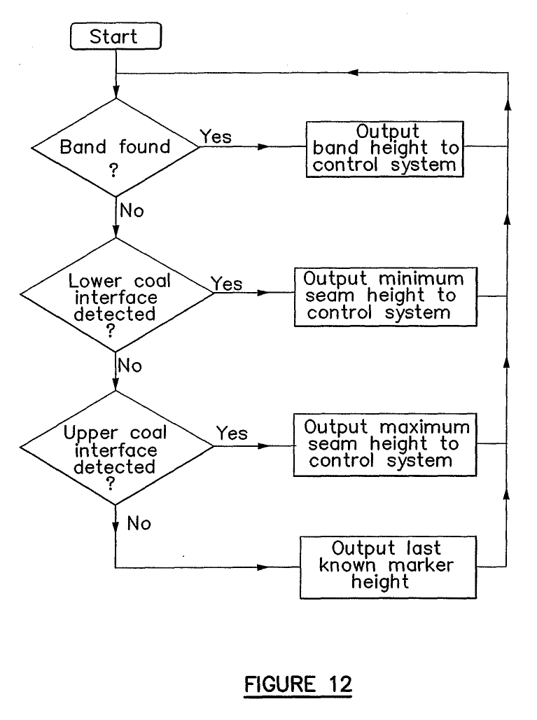

FIG. 12 shows how the outputs of the band or feature 33 tracking and the interface detection systems can be combined to provide a robust datum for horizon control. Thus, if it should occur that a primary and preferred mode of operation using the band or feature 33 is not available, then an output selector can be operated to use the reactive (and coarser) coal seam boundary interface signals for horizon control. If the band or feature 33 tracking signals are provided and no interface intersection signals are provided, the system can output, depending on mine site's specific horizon control policy, the last band or feature 33 output signals, half seam extraction height signals or zero signals. Here, at step 1, a marker band assessment is made to determine if a band or feature 33 is present. If present, an output height signal is provided at step 2. If no band or feature 33 is determined, then at step 3 an assessment is made as to whether a floor coal interface is detected. If it is detected then an output signal is determined to indicate the height of the floor. If no floor interface is detected then an assessment is made at step 5 as to whether a roof intersection is detected. If it is detected then an output signal is provided to indicate the height of the roof 17. If no interface is detected then step 7 provides the last known band height output signals.

In order to achieve horizon control of a mining machine such as a longwall mining shearer, the output of the band or feature 33 tracking system is fed into an existing mining machine shearer arm 13 control system. The arms 13 are the principal method for adjusting the horizon (horizontal) position of the longwall shearer machine 9 as it extracts product 3 such as coal. Corrections to the mining horizon are usually applied on each backwards and forwards traverse cycle of the mining machine 9 along the rail means 15. The band or feature 33 height signals may be acted upon by the control system in an instantaneous manner using the observed heights. This is because any variation in the height is expected to be quite minimal. If required, the height locations at various positions along the face of the mine may be stored in memory and subsequently retrieved on a next backwards or forward traverse cycle of the mining machine 9 where they can be retrieved and compared with any newly measured height positions of the bands or features 33.

Account may be taken of the dynamics of the mining machine 9 control system noting the specific mechanical limitations of the cutter drum 11 and any desired horizon profile rate of change to provide a safe and practical control.

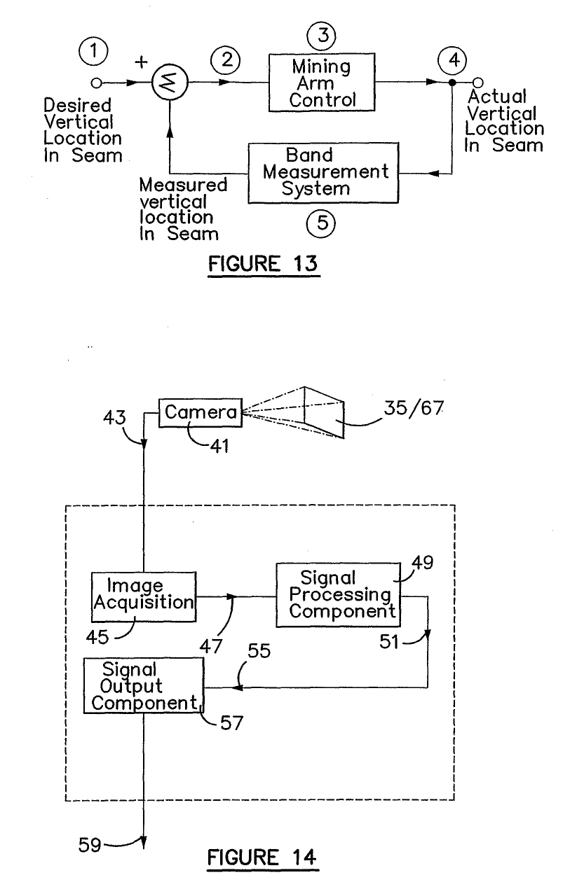

FIG. 13 is a block schematic diagram showing a general arrangement for the automation of the horizon control in a mining machine 9. A desired vertical location within the seam 1 is typically a fixed offset from the band or feature 33 height location. Here at step 1 a desired horizon set point is established. At step 2 a command (position error) signal is provided to the arm position control system at step 3. At step 4 an actual vertical location of the mining machine 9 is determined within the seam. At step 5, the combined band and feature 33 system and the interface detection system provide a vertical position sensing capability to provide for a control loop.

A system of the above type is useful in automated control systems for mining coal in a longwall mining and minimises equipment damage whilst increasing productivity and improving personnel safety. Using the methods herein no external reference infrastructure such as beacons, markers, stripes are required for operation. Thus, there is increased practicality and robustness of mining machines utilising the concepts herein. The principles herein can operate in either real-time or offline. The techniques disclosed herein represent automatic, online, self-regulating methods for roof or floor detection and band or feature 33 detection for horizontal control. Further, the co-ordinate position output signals of the band or feature 33 positions or the interface positions of the roof 17 or floor 19 can be used in mining survey processes to greatly enhance mining operations.

It should also be appreciated that the band or feature 33 system described herein can be utilised for identifying thermally identifiable structure in a mined product when mining that product from a mine. Thus, by noting the IR image signals of an observed position of a freshly exposed cut product face immediately adjacent the mining machine cutter, one can obtain signals which can be useable to identify thermally identifiable structure in the mined product. The thermally identifiable structure can be identified by either noting the size magnitude (i.e. the number of high intensity pixel) of the at least one temperature contrast region, or noting the magnitude of the at least one temperature contrast region above a temperature threshold. An output signal can be provided from an output component to indicate thermally identifiable structure in the mined product. In this example, FIG. 7 shows the necessary signal processing components where the output signal 59 provides an indication of the thermally identifiable product. A specific circuit diagram is shown in FIG. 14. Here, the digital video camera 41 will provide output signals 43 to the image acquisition component 45. The image acquisition component 45 will process the signals 43 in the same way as explained in relation to the FIG. 7. Output signals 47 will be provided to the signal processing component 49 which can sense if the IR temperature pixel intensity values exceed a particular threshold, and provide an output signal 51 to the signal output component 57 which will, in turn, provide an output signal 59 indicating the presence or absence of thermally identifiable structure in the mined product. Thus, in this embodiment, the signal processing component 49 can note either the size magnitude of the at least one temperature contrast region, or if the temperature contrast region has a magnitude above a temperature threshold.

Modifications may be made to the invention as would be apparent to persons skilled in the mining machine control arts. These and other modifications may be made without departing from the ambit of the invention the nature of which is to be determined from the foregoing description.

1. A method of horizon control in a mining operation where mined product is cut from a mining face of a seam of the product, said method comprising,
cutting product from the seam with a cutter that exposes a fresh cut product face
observing the IR (Infrared) radiation from the fresh cut product face at a position immediately adjacent the cutter,
noting any temperature contrast regions from the IR observation between an upper limit of observation and a lower limit of observation,
determining at least one height co-ordinate position of at least one temperature contrast region, and
generating an output signal of the determined height co-ordinate position so the generated output signal can be used as a horizon datum for horizon control.

2. A method as claimed in claim 1 including applying a threshold filter to the noted temperature contrast region and generating the output signal of the determined height co-ordinate position only if the temperature of the temperature contrast region exceeds the threshold.

3. A method as claimed in claim 1 wherein a field of viewing the observation of the IR radiation is provided with a datum position in a horizontal axis direction that extends in a vertical axis direction up and down the height of a region of interest for the IR radiation, and wherein the at least one temperature contrast region from the IR observation is determined at that datum position.

4. A method as claimed in claim 3 wherein the observing is by a digital camera and wherein the datum position is defined by specific pixel locations in a digital picture image obtained from said digital camera.

5. A method as claimed in claim 4 wherein the temperature contrast regions are determined by noting a peak in the pixel grey scale intensity values over many pixels at the datum position in the digital image extending in a direction up and down the height of the region of interest.

6. The method as claimed in claim 1 wherein the height co-ordinate position output signal is a signal containing co-ordinate components that define the position of at least one temperature contrast region in two D co-ordinates.

7. A method as claimed in claim 1 comprising supplying the height co-ordinate position output signal to a mining machine cutter position control circuit used by a mining machine, and horizon controlling the position of the mining machine cutter with said position output signal.

8. A method as claimed in claim 7 wherein a region of interest for the IR radiation is provided with a datum position in a horizontal axis direction that extends in a vertical axis direction up and down the height of the region of interest, and wherein the at least one temperature contrast region from the IR observation is determined at that datum position,
and wherein the observing results in a digital picture image and the datum position is defined by specific pixel locations the digital picture image, and wherein
the at least one temperature contrast region is determined by noting a peak in the pixel grey scale intensity values over many pixels at the datum position in the digital image.

9. A method as claimed in claim 1 comprising also visually observing the IR radiation from the fresh cut product face, noting a second temperature contrast region, generally at the intersection of a vertical cut of a wall of a seam of the product and a horizontal cut face of a roof and/or floor of the seam of the product,
determining a height co-ordinate position of the second temperature region to define the roof and/or floor co-ordinate(s) of the seam of the product, and
generating a second output signal of the determined height co-ordinate position of the second temperature contrast region so the second output signal can be used with said output signal for horizon control.

10. A method as claimed in claim 9 wherein the observation for the second temperature contrast region results in a digital picture image of a second region of interest and wherein grey scale pixel intensity values of all pixels in the digital image of the second region of interest are averaged and a lower and/or an upper limit for mining the seam of the product is noted if the average pixel intensity value changes to a higher average pixel intensity value than when cutting only product from the seam.

11. A method as claimed in claim 10 wherein the region of interest of the IR radiation is provided with a datum position in a horizontal axis direction that extends in a vertical axis direction up and down the height of the region of interest, and wherein the at least one temperature contrast region from the IR observation is determined at that datum position,
and wherein the observing is by a thermal infrared camera and the datum position is defined by specific pixel locations in a digital picture image obtained therefrom and wherein the at least one temperature contrast region is determined by noting a peak in the pixel grey scale intensity values over many pixels at the datum position in the digital image extending in a direction up and down the height of viewing.

12. A method as claimed in claim 6 wherein the observation of the position of the IR radiation is performed at multiple spaced locations in the fresh cut product face, as the cutter moves across the mine face, and wherein multiple temperature contrast regions are determined from those multiple locations and wherein a “Robust Tracking” filter is applied to the multiple temperature contrast regions to minimise errors that may otherwise be caused by low levels of temperature contrast.

13. A sensing apparatus for operating with mining machine horizon controlling apparatus,
said sensing apparatus having an image acquisition section for receiving IR (Infrared) image signals of an observed position of a fresh cut mined product face immediately adjacent a mining machine cutter
a signal processing component to process the acquired IR image signals to note for at least one temperature contrast region between an upper part of the image and a lower part of the image,
a height position component to receive any noted temperature contrast region processed by the signal processing component and to calculate a height position at at least one noted temperature contrast region, and
a signal output component to provide an output signal of the calculated height position for said mining machine horizon controlling apparatus.

14. A sensing apparatus claimed in claim 13 wherein the signal processing component includes a threshold filter for the noted temperature contrast region and wherein the signal output component generates the output signal of the determined height co-ordinate position only if the temperature of the temperature contrast region exceeds the threshold.

15. A sensing apparatus as claimed in claim 13 wherein said signalling processing component is configurable to provide a region of interest for the IR radiation with a datum position in the horizontal axis direction that extends in a vertical axis direction up and down the height of the region of interest, and wherein the at least one temperature contrast region processed by the height position component is determinable at that datum position.

16. A sensing apparatus as claimed in claim 15 wherein the observing results in a digital picture image and wherein the datum position is defined in said signal processing component by specific pixel locations in the digital picture image.

17. A sensing apparatus as claimed in claim 16 wherein the signal processing component is configurable to determine the temperature contrast region by noting a peak in the pixel grey scale intensity values over many pixels at the datum position in the digital picture image extending in a direction up and down the height of the region of interest.

18. A sensing apparatus as claimed in claim 13 wherein the height co-ordinate position output signal from the output signal component is a signal that defines the position of the temperature contrast region in two D co-ordinates.

19. A sensing apparatus as claimed in claim 13 wherein the height co-ordinate position output signal is suppliable to mining machine cutter position control apparatus used by a mining machine, so horizontal control of the position of the mining machine cutter can be undertaken with said position output signal.

20. A sensing apparatus as claimed in claim 19 wherein the signal processing component is configurable to provide a region of interest for the observation of the IR radiation that has a datum position in the horizontal axis direction that extends in a vertical axis direction up and down the height of the field of viewing of the IR radiation, and the at least one temperature contrast region is determined at that datum position,
and wherein the observing is by a thermal infrared camera and the datum position is defined by specific pixel locations in a digital picture image obtained therefrom, and
wherein the temperature contrast region is determined by noting a peak in the pixel grey scale intensity values over many pixels at the datum position in the digital image that extend in a direction up and down the height of the region of interest.

21. A sensing apparatus as claimed in claim 13 wherein said sensing apparatus image acquisition section also receives further IR image signals of the fresh cut product face generally at the intersection of a vertical cut face of a wall of the seam and a horizontal cut face of a roof and/or floor of the seam, and
wherein said signal processing component can process the further IR image signals to note for any temperature contrast region at the intersection of the vertical cut face and either or both the horizontal cut face of the roof or the floor and wherein the height determining component can determine a height co-ordinate position of the temperature contrast region to define the roof and/or floor co-ordinates of the seam of the product, and wherein the signal output component can generate a second output signal indicating the determined height co-ordinate position of the temperature contrast region at the intersection so the second output signal can be used with said output signal for horizon control.

22. A sensing apparatus as claimed in claim 21 wherein the observation for the second temperature contrast region is by a thermal infrared camera and wherein the height position component can average the grey scale pixel intensity values of all pixels in a digital image thereof and note a lower and/or an upper limit for mining the seam of the product should the average intensity value change to a higher average pixel intensity value than when cutting only product from the seam.

23. A sensing apparatus as claimed in claim 22 wherein the signal processing component provides a datum position in a horizontal axis direction that extends in a vertical axis direction up and down the height of a region of interest for the IR radiation, and wherein the temperature contrast region is determined by the signal processing component at that datum position,
said datum position being definable by specific pixel locations in a digital picture image obtained from the thermal infrared camera, and
said at least one temperature contrast region being determinable by noting a peak in the pixel grey scale intensity values over many pixels at the datum position in the digital image that extend in a direction up and down the height of the region of interest.

24. A sensing apparatus as claimed in claim 18 wherein the observing of the position of the IR radiation is at multiple locations in the fresh cut product face, as the cutter moves across the mine face, and wherein multiple temperature contrast regions are determined from those multiple locations and said signal processing component applies a “Robust Tracking” filter to the multiple temperature contrast regions to minimise errors that may otherwise be caused by low levels of temperature contrast.

25. An apparatus as claimed in claim 13 and interconnected with a mining machine horizontal control apparatus.

26. A method of identifying thermally identifiable structure in a product mined from a mining face in a mine where a cutter cuts the product and exposes a fresh cut product face,
said method comprising observing the IR radiation from the fresh cut product face immediately adjacent the cutter,
noting at least one temperature contrast region from the IR observation and determining a thermally identifiable structure in the product mined by either;
1. the size magnitude of the at least one temperature contrast region or,
2. the temperature of the contrast region exceeding a temperature threshold.

27. A method as claimed in claim 26 wherein a region of interest for the IR radiation is provided with a datum position in a horizontal axis direction that extends in a vertical axis direction up and down the height of the region of interest, and wherein the size magnitude of the temperature contrast region is determined at that datum position.

28. A method as claimed in claim 26 wherein a region of interest for the IR radiation is provided with a datum position in the horizontal axis direction that extends in a vertical axis direction up and down the height of the region of interest, and wherein the at least one temperature contrast region is determined at that datum position,
and wherein the observing is by a thermal infrared camera and the datum position is defined by specific pixel locations in a digital picture image in the region of interest, and the at least one temperature contrast region is determined by noting a pixel grey scale peak in the intensity values over many pixels at the datum position in the digital image extending in a direction up and down the height of the region of interest.

29. A method as claimed in claim 26 wherein a region of interest of the IR radiation is provided with a datum position in the horizontal axis direction that extends in a vertical axis direction up and down the height of the region of interest and wherein the at least one temperature contrast region from the IR observation is determined at that datum position,
and wherein the observing is by a thermal infrared camera and the datum position is defined by specific pixel locations in a digital picture image obtained therefrom,
and wherein the at least one temperature contrast region is determined by noting a peak in the pixel grey scale intensity values over many pixels at the datum position in the digital image extending in a direction up and down the height of the region of interest.

30. An apparatus to identify thermally identifiable structure in a mined product when mining product from a mine,
said apparatus having an image acquisition section for receiving IR image signals of an observed position of a freshly exposed cut product face immediately adjacent a mining machine cutter that cuts product from the mine,
a signal processing component to process the acquired IR image signals to note for at least one temperature contrast region,
an image processing component to identify thermally identifiable structure of the mined product by either
1. noting the size magnitude of the at least one temperature contrast region, or
2. noting the temperature magnitude of the at least one temperature contrast region above a temperature threshold, and
an output component to provide an output indicating thermally identifiable structure in the mine product.
